(19) United States
(12) Patent Application Publication
(10) Pub. No.: US 2015/0128004 A1
(43) Pub. Date: May 7, 2015

(54) Constellation mapping for communication systems

(71) Applicant: BROADCOM CORPORATION, Irvine, CA (US)

(72) Inventors: Tak Kwan Lee, Irvine, CA (US); Ba-Zhong Shen, Irvine, CA (US)

(73) Assignee: BROADCOM CORPORATION, IRVINE, CA (US)

(21) Appl. No.: 14/525,425

(22) Filed: Oct. 28, 2014

Related U.S. Application Data
(60) Provisional application No. 61/900,285, filed on Nov. 5, 2013.

(51) Int. Cl. H03M 13/25; H04L 1/00

(52) U.S. Cl. CPC H03M 13/25; H04L 1/0057; H04L 1/0041
USPC 714/746

(57) ABSTRACT

A communication device (or device) includes a communication interface and processor that support communications with one or more other devices within a communication system. The processor generates and interprets different signals, frames, packets, symbols, etc. for transmission to other devices and that have been received from other devices. The device generates modulation symbols based on two-dimensional (2-D) symbol locations of a constellation. The device generates the 2-D symbol locations using based on recursive one-dimensional (1-D) Gray code formula applied to bits of symbol values. The recursive 1-D Gray code formula specifies first symbol locations for symbol values having a first number of bits (e.g., n) based on second symbol locations for other symbol values having one fewer bits per symbol (e.g., n−1). The device maps data symbols to the 2-D symbol locations to generate the modulation symbols and transmits the modulation symbols to another communication device.

### CROSS REFERENCE TO RELATED PATENTS/PATENT APPLICATIONS

### Provisional Priority Claim

The present U.S. Utility patent application claims priority pursuant to 35 U.S.C. §119(e) to U.S. Provisional Application No. 61/900,285, entitled “Constellation mapping for LDPC coding,” filed Nov. 5, 2013, which is hereby incorporated herein by reference in its entirety and made part of the present U.S. Utility patent application for all purposes.

### BACKGROUND

1. Technical Field

The present disclosure relates generally to communication systems; and, more particularly, to constellation generation and mapping within such communication systems.

2. Description of Related Art

Data communication systems have been under continual development for many years. The primary goal within such communication systems is to transmit information successfully between devices. Unfortunately, many things can deleteriously affect signals transmitted within such systems resulting in degradation of or even complete failure of communication. Examples of adverse effects include interference and noise that may be caused by various sources including other communications, low-quality links, degraded or corrupted interfaces and connectors, etc.

Some communication systems use forward error correction (FEC) coding and/or error correction code (ECC) coding to increase the reliability and the amount of information that may be transmitted between devices. When a signal incurs one or more errors during transmission, a receiver device can employ the FEC or ECC coding to try to correct those one or more errors. In addition, some communication systems use modulation coding that maps digital information to constellation points having symbol labels within a constellation.

There continues to be a great deal of room to increase the amount of information that can be transmitted between communication devices within communication systems. A continual and primary directive in this area of development has been to try continually to lower the signal to noise ratio (SNR) required to achieve a given bit error ratio (BER) or symbol error ratio (SER) within a communication system. The Shannon limit is the theoretical bound for channel capacity for a given modulation and code rate. The ideal goal has been to try to reach Shannon's channel capacity limit in a communication channel. Shannon's limit may be viewed as being the data rate per unit of bandwidth (i.e., spectral efficiency) to be used in a communication channel, having a particular SNR, where transmission through the communication channel with arbitrarily low BER or SER is achievable. There continues to be a great deal of room for improvement in the generation of types of constellations and the generation of symbol labels for the constellation points within such constellations in efforts to increase throughput, reliability, performance, etc.

### BRIEF DESCRIPTION OF THE SEVERAL VIEWS OF THE DRAWINGS

FIG. 1A is a diagram illustrating an embodiment of one or more communication systems.

FIG. 1B is a diagram illustrating another embodiment of one or more communication systems.

FIG. 2A is a diagram illustrating a communication device (CD) operative within one or more communication systems.

FIG. 2B is a diagram illustrating a communication device (CD) operative within one or more communication systems.

FIG. 2C is a diagram illustrating an example of generation of a constellation mapping for data symbols.

FIG. 3A is a diagram illustrating an example of encoding and symbol mapping and symbol de-mapping and decoding.

FIG. 3B is a diagram illustrating an example of symbol values.

FIG. 3C is a diagram illustrating an example of Gray code mapping for integers (e.g., 2^{k} integers) in one-dimension.

FIG. 3D is a diagram illustrating another example of symbol values partitioned into most significant bits (MSBs) and least significant bits (LSBs).

FIG. 3E is a diagram illustrating an example of Gray code mapping for integers (e.g., 2^{k} integers) in two-dimensions.

FIG. 4A is a diagram illustrating another example of generation of a constellation mapping for data symbols based on MSBs and LSBs.

FIG. 4B is a diagram illustrating an example of Gray code mapping for integers in two-dimensions that results in a rectangle-shaped constellation.

FIG. 4C is a diagram illustrating an example of transformation of a rectangle-shaped constellation to a cross-shaped constellation (based on FIG. 4B).

FIG. 4D is a diagram illustrating an example of shifting of a cross-shaped constellation to center the cross-shaped constellation around an origin (based on FIG. 4C).

FIG. 4E is a diagram illustrating an example of Gray code mapping for integers in two-dimensions that results in a square-shaped constellation.

FIG. 5A is a diagram illustrating an example of Gray code mapping for integers in two-dimensions for cross-shaped constellations (e.g., 2²ⁿ⁺¹ QAM, where n>1).

FIG. 5B is a diagram illustrating another example of Gray code mapping for integers in two-dimensions for cross-shaped constellations (e.g., 2²ⁿ⁺¹ QAM, where n>1).

FIG. 6A is a diagram illustrating another example of transformation of a rectangle-shaped constellation to a cross-shaped constellation.

FIG. 6B is a diagram illustrating another example of transformation of a rectangle-shaped constellation to a cross-shaped constellation (based on FIG. 6A).

FIG. 7A is a diagram illustrating an embodiment of a method for execution by one or more communication devices.

FIG. 7B is a diagram illustrating another embodiment of a method for execution by one or more communication devices.

FIG. 7C is a diagram illustrating another embodiment of a method for execution by one or more communication devices.

### DETAILED DESCRIPTION

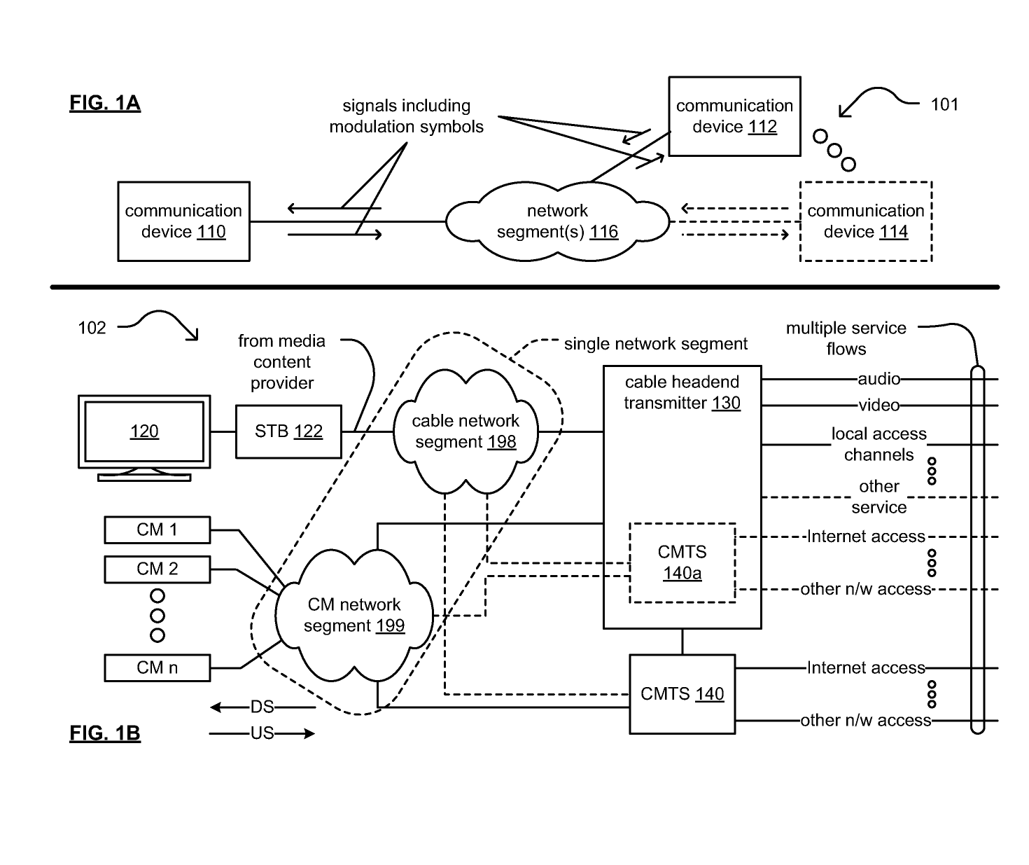

FIG. 1A is a diagram illustrating an embodiment 101 of one or more communication systems. One or more network segments 116 provide communication inter-connectivity for at least two communication devices 110 and 112 (also referred to as CDs in certain locations in the diagrams). Note that general reference to a communication device may be made generally herein using the term ‘device’ (e.g., device 110 or CD 110 when referring to communication device 110, or devices 110 and 112, or CDs 110 and 112, when referring to communication devices 110 and 112). Generally speaking, any desired number of communication devices are included within one or more communication systems (e.g., as shown by communication device 114).

The various communication links within the one or more network segments 116 may be implemented using any of a variety of communication media including communication links implemented as wireless, wired, optical, satellite, microwave, and/or any combination thereof, etc. communication links. Also, in some instances, communication links of different types may cooperatively form a connection pathway between any two communication devices. Considering one possible example, a communication pathway between devices 110 and 112 may include some segments of wired communication links and other segments of optical communication links. Note also that the devices 110-114 may be of a variety of types of devices including stationary devices, mobile devices, portable devices, etc. and may support communications for any of a number of services or service flows including data, telephony, television, Internet, media, synchronization, etc.

In an example of operation, device 110 includes a communication interface to support communications with one or more of the other devices 112-114. This communication may be bidirectional/to and from the one or more of the other devices 112-114 or unidirectional (or primarily unidirectional) from the one or more of the other devices 112-114.

In an example of operation, one of the devices, such as device 110, includes a communication interface and a processor that cooperatively operate to support communications with another device, such as device 112, among others within the system. The processor is operative to generate and interpret different signals, frames, packets, symbols, etc. for transmission to other devices and that have been received from other devices. The device 110 generates modulation symbols based on two-dimensional (2-D) symbol locations of a constellation. The device 110 generates or determines the 2-D symbol locations based on recursive one-dimensional (1-D) Gray code formula applied to bits of symbol values. The recursive 1-D Gray code formula specifies first symbol locations for symbol values having a first number of bits (e.g., n) based on second symbol locations for other symbol values having one fewer bits per symbol (e.g., n−1). The device 110 maps data symbols to the 2-D symbol locations to generate the modulation symbols and transmits the modulation symbols to another communication device.

In an example of operation, the device 110 generates first 2-D symbol locations for a constellation based on a recursive 1-D Gray code formula applied to symbol values. In one implementation, the device 110 applies the recursive 1-D Gray code formula to a first at least one bit and a second at least one bit of each symbol value of the symbol values. The 1-D Gray code formula specifies a first 1-D Gray code symbol location for a first symbol value based on a second 1-D Gray code symbol location for a second symbol value having one fewer bits per symbol than the first symbol value. Consider symbol values having k bits (e.g., b₀b₁ . . . bₖ₋₁), then symbol locations for symbol values b₀b₁ . . . bₖ₋₁ are recursively generated using symbol locations for symbol values having one fewer bits (e.g., b₁ . . . bₖ₋₁).

After generating the first 2-D symbol locations, the device 110 determines whether the first 2-D symbol locations form a square-shaped constellation. If they do form a square-shaped constellation, the device 110 maps data symbols to the first 2-D symbol locations to generate modulation symbols. In some instances, the device 110 generates the data symbols by encoding information bits using a forward error correction (FEC) code and/or error correction code (ECC).

Alternatively, if they do form a square-shaped constellation, the device 110 transforms the first 2-D symbol locations to second 2-D symbol locations by re-assigning a first subset and a second subset of the first 2-D symbol locations. These second 2-D symbol locations form a cross-shaped constellation. The device 110 then maps the data symbols to the second 2-D symbol locations to generate the modulation symbols.

Then, after the device 110 generates the modulation based on either the first or second 2-D symbol locations, the device 110 transmits the modulation symbols to another communication device (e.g., device 112) (e.g., in a signal, a frame, a packet, a transmission, etc.).

In another example of operation, the device 110 receives other modulation symbols from device 112 that have been generated by device 112. The device 110 processes these other modulation symbols to make estimates of data symbols therein. When the data symbols are generated based on FEC code and/or ECC encoding, the device 110 decodes the data symbols to make estimates of information bits encoded therein.

FIG. 1B is a diagram illustrating another embodiment 102 of one or more communication systems. A cable headend transmitter 130 provides service to a set-top box (STB) 122 via cable network segment 198. The STB 122 provides output to a display capable device 120. The cable headend transmitter 130 can support any of a number of service flows such as audio, video, local access channels, as well as any other service of cable systems. For example, the cable headend transmitter 130 can provide media (e.g., video and/or audio) to the display capable device.

The cable headend transmitter 130 may provide operation of a cable modem termination system (CMTS) 140a. For example, the cable headend transmitter 130 may perform such CMTS functionality, or a CMTS may be implemented separately from the cable headend transmitter 130 (e.g., as shown by reference numeral 140). The CMTS 140 can provide network service (e.g., Internet, other network access, etc.) to any number of cable modems (shown as CM 1, CM 2, and up to CM n) via a cable modem (CM) network segment 199. The cable network segment 198 and the CM network segment 199 may be part of a common network or common networks. The cable modem network segment 199 couples the cable modems 1-n to the CMTS (shown as 140 or 140a). Such a cable system (e.g., cable network segment 198 and/or CM network segment 199) may generally be referred to as a cable plant and may be implemented, at least in part, as a hybrid fiber-coaxial (HFC) network (e.g., including various wired and/or optical fiber communication segments, light sources, light or photo detection complements, etc.).

A CMTS 140 (or 140a) is a component that exchanges digital signals with cable modems 1-n on the cable modem network segment 199. Each of the cable modems is coupled to the cable modem network segment 199, and a number of elements may be included within the cable modem network segment 199. For example, routers, splitters, couplers, relays, and amplifiers may be contained within the cable modem network segment 199. Generally speaking, downstream information may be viewed as that which flows from the CMTS 140 to the connected cable modems (e.g., CM 1, CM2, etc.), and upstream information as that which flows from the cable modems to the CMTS 140.

In an example of operation, the CM 1 generates first 2-D symbol locations for a constellation based on a recursive 1-D Gray code formula applied to symbol values. After generating the first 2-D symbol locations, the CM 1 determines whether the first 2-D symbol locations form a square-shaped constellation. If they do form a square-shaped constellation, the CM 1 maps data symbols to the first 2-D symbol locations to generate modulation symbols. In some instances, the CM 1 generates the data symbols by encoding information bits using a forward error correction (FEC) code and/or error correction code (ECC).

Alternatively, if they do form a square-shaped constellation, the CM 1 transforms the first 2-D symbol locations to second 2-D symbol locations by re-assigning a first subset and a second subset of the first 2-D symbol locations. This second 2-D symbol locations form a cross-shaped constellation. The CM 1 then maps the data symbols to the second 2-D symbol locations to generate the modulation symbols.

Then, after the CM 1 generates the modulation based on either the first or second 2-D symbol locations, the CM 1 transmits the modulation symbols to another communication device (e.g., CMTS 140) (e.g., in a signal, a frame, a packet, a transmission, etc.).

In another example of operation, the CM 1 receives other modulation symbols from CMTS 140 that have been generated by CMTS 140. The CM 1 processes these other modulation symbols to make estimates of data symbols therein. When the data symbols are generated based on FEC code and/or ECC encoding, the CM 1 decodes the data symbols to make estimates of information bits encoded therein.

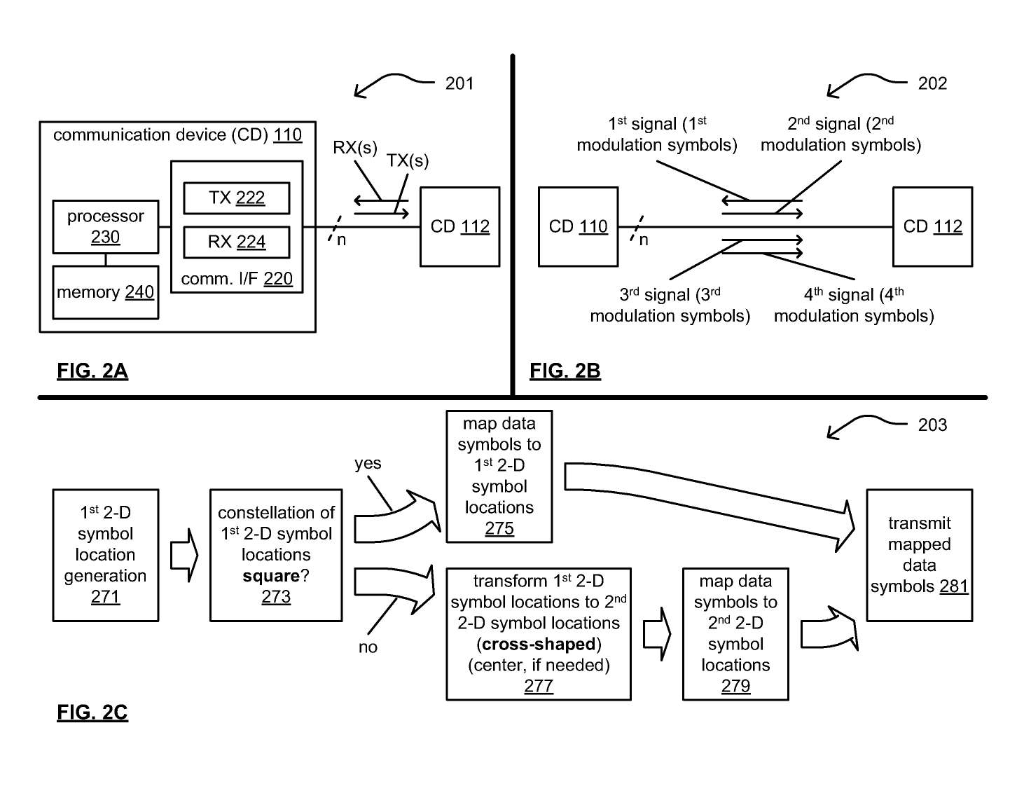

FIG. 2A is a diagram 201 illustrating a communication device (CD) 110 operative within one or more communication systems. The device 110 includes a communication interface 220 and a processor 230. The communication interface 220 includes functionality of a transmitter 222 and a receiver 224 to support communications with one or more other devices within a communication system. The device 110 may also include memory 240 to store information including one or more signals generated by the device 110 or such information received from other devices (e.g., device 112) via one or more communication channels. Memory 240 may also include and store various operational instructions for use by the processor 230 in regards to the processing of messages and/or other received signals and generation of other messages and/or other signals including those described herein. Memory 240 may also store information including one or more types of encoding, one or more types of symbol mapping, concatenation of various modulation coding schemes, etc. as may be generated by the device 110 or such information received from other devices via one or more communication channels. The communication interface 220 supports communications to and from one or more other devices (e.g., CD 112 and/or other communication devices). Operation of the communication interface 220 may be directed by the processor 230 such that processor 230 transmits and receives signals (TX(s) and RX(s)) via the communication interface 220.

Note that device 110 may be implemented to operate as any one or more of a satellite communication device, a wireless communication device, a wired communication device, a fiber-optic communication device, or a mobile communication device and implemented and/or operative within any one or more communication systems including a satellite communication system, a wireless communication system, a wired communication system, a fiber-optic communication system, or a mobile communication system.

In an example of operation, processor 230 generates a first plurality of 2-D symbol locations for a constellation based on a recursive 1-D Gray code formula applied to a first at least one bit and a second at least one bit of each symbol value of a plurality of symbol values. The recursive 1-D Gray code formula specifies a first 1-D Gray code symbol location for a first symbol value based on a second 1-D Gray code symbol location for a second symbol value having one fewer bits per symbol than the first symbol value. The processor 230 then determines whether the first plurality of 2-D symbol locations form a square-shaped constellation. When the first plurality of 2-D symbol locations form the square-shaped constellation, the processor 230 maps a plurality of data symbols to the first plurality of 2-D symbol locations to generate a plurality of modulation symbols.

When the first plurality of 2-D symbol locations do not form a square-shaped constellation, the processor 230 transforms the first plurality of 2-D symbol locations to a second plurality of 2-D symbol locations by re-assigning a first subset and a second subset of the first plurality of 2-D symbol locations. The second plurality of 2-D symbol locations form a cross-shaped constellation. The processor 230 then maps the plurality of data symbols to the second plurality of 2-D symbol locations to generate the plurality of modulation symbols.

Then, the processor 230 transmits, via the communication interface 220, the plurality of modulation symbols, which have been generated based on the first or second plurality of 2-D symbol locations, to another communication device (e.g., device 112).

In another example of operation, the processor 230 receives, via the communication interface 220, other modulation symbols from device 112 that have been generated by device 112. The processor 230 processes these other modulation symbols to make estimates of data symbols therein. When the data symbols are generated based on FEC code and/or ECC encoding, the processor 230 decodes the data symbols to make estimates of information bits encoded therein.

Note also that processor 230 may be implemented to perform encoding of one or more bits to generate one or more coded bits or data symbols used to generate the modulation symbols or modulation data (or generally, data). For example, the processor 230 may be configured to perform forward error correction (FEC) code and/or error correction code (ECC) coding of one or more bits to generate one or more coded bits. Examples of FEC code and/or ECC may include turbo code, convolutional code, turbo trellis coded modulation (TTCM), low density parity check (LDPC) code, Reed-Solomon (RS) code, BCH (Bose and Ray-Chaudhuri, and Hocquenghem) code, etc. The one or more coded bits may then undergo modulation or symbol mapping to generate modulation symbols. The modulation symbols may include data intended for one or more recipient devices. Note that such modulation symbols may be generated using any of various types of modulation coding techniques. Examples of such modulation coding techniques may include binary phase shift keying (BPSK), quadrature phase shift keying (QPSK), 8-phase shift keying (PSK), 16 quadrature amplitude modulation (QAM), 32 amplitude and phase shift keying (APSK), etc., uncoded modulation, and/or any other desired types of modulation including higher ordered modulations that may include even greater number of constellation points (e.g., 1024 QAM, etc.). The particular 2-D symbol locations of a given modulation coding technique can be generated as described herein using the recursive 1-D Gray code formula appropriately applied.

In an example of operation, the processor 230 determines whether the second plurality of 2-D symbol locations are centered around the origin of the cross-shaped constellation. When the second plurality of 2-D symbol locations are not centered around the origin of the cross-shaped constellation, the processor 230 shifts the second plurality of 2-D symbol locations along an axis of the cross-shaped constellation to center the second plurality of 2-D symbol locations around an origin of the cross-shaped constellation.

In another example of operation, the processor 230 applies the recursive 1-D Gray code formula to a most significant at least one bit of one of the plurality of symbol values to generate a first axis coordinate value of one of the first plurality of 2-D symbol locations and also applies the recursive 1-D Gray code formula to a least significant at least one bit of the one of the plurality of symbol values to generate a second axis coordinate value of the one of the first plurality of 2-D symbol locations. The symbol values may include an even or odd number of bits. For example, when the symbol values may include an odd number of bits, the most significant at least one bit includes one bit more or one bit fewer than the least significant at least one bit. For another example, when the symbol values may include an even number of bits, the most significant at least one bit includes a same number of bits as the least significant at least one bit.

In another example of operation, the processor 230 re-assigns a first 2-D symbol location within the first subset of the first plurality of 2-D symbol locations from a wing of the first plurality of 2-D symbol locations to above the first plurality of 2-D symbol locations and also re-assigns a second 2-D symbol location within the first subset of the first plurality of 2-D symbol locations from the wing of the first plurality of 2-D symbol locations to below the first plurality of 2-D symbol locations to generate the second plurality of 2-D symbol locations.

In another example of operation, the processor 230 encodes a plurality of information bits using a low density parity check (LDPC) code to generate the plurality of data symbols. In another example of operation, the processor 230 encodes a plurality of information bits using a Reed-Solomon (RS) code or a BCH (Bose and Ray-Chaudhuri, and Hocquenghem) code to generate the plurality of data symbols. The processor 230 can perform encoding using any one or more FEC codes and/or ECCs to generate the data symbols.

FIG. 2B is a diagram 202 illustrating a communication device (CD) 110 operative within one or more communication systems. Device 110 supports communications to and from one or more other devices, such as device 112. In an example of operation, device 110 transmits a 1^{st} signal that includes 1^{st} modulation symbols to device 112. In another example of operation, device 110 receives a 2^{nd} signal that includes 2^{nd} modulation symbols from device 112. The 1^{st} and 2^{nd} modulation symbols may be based on the same or different 2-D symbol locations of a given modulation coding technique and/or the same or different one or more FEC codes and/or ECCs.

In another example of operation, device 110 transmits a 3^{rd} signal that includes 3^{rd} modulation symbols to device 112 and also transmits a 4^{th} signal that includes 4^{th} modulation symbols to device 112. The 3^{rd} and 4^{th} modulation symbols may be based on the same or different 2-D symbol locations of a given modulation coding technique and/or the same or different one or more FEC codes and/or ECCs. Different respective signals including different respective modulation symbols may be generated and transmitted at different times.

FIG. 2C is a diagram illustrating an example 203 of generation of a constellation mapping for data symbols. The generation process operates to generate a first plurality of two-dimensional symbol locations for a constellation based on a recursive one-dimensional Gray code formula applied to a first at least one bit and a second at least one bit of each symbol value of a plurality of symbol values (block 271). The recursive one-dimensional Gray code formula specifies a first one-dimensional Gray code symbol location for a first symbol value based on a second one-dimensional Gray code symbol location for a second symbol value having one fewer bits per symbol than the first symbol value.

The generation process operates to determine whether the first plurality of two-dimensional symbol locations form a square-shaped constellation (block 273). The generation process operates to map a plurality of data symbols to the first plurality of two-dimensional symbol locations to generate a plurality of modulation symbols when the first plurality of two-dimensional symbol locations form the square-shaped constellation (block 275).

The generation process operates to transform the first plurality of two-dimensional symbol locations to a second plurality of two-dimensional symbol locations by re-assigning a first subset and a second subset of the first plurality of two-dimensional symbol locations when the first plurality of two-dimensional symbol locations do not form a square-shaped constellation (block 277). The second plurality of two-dimensional symbol locations form a cross-shaped constellation. The generation process also operates to map the plurality of data symbols to the second plurality of two-dimensional symbol locations to generate the plurality of modulation symbols when the first plurality of two-dimensional symbol locations do not form a square-shaped constellation (block 279).

The generation process operates to transmit the plurality of modulation symbols to another communication device (block 281).

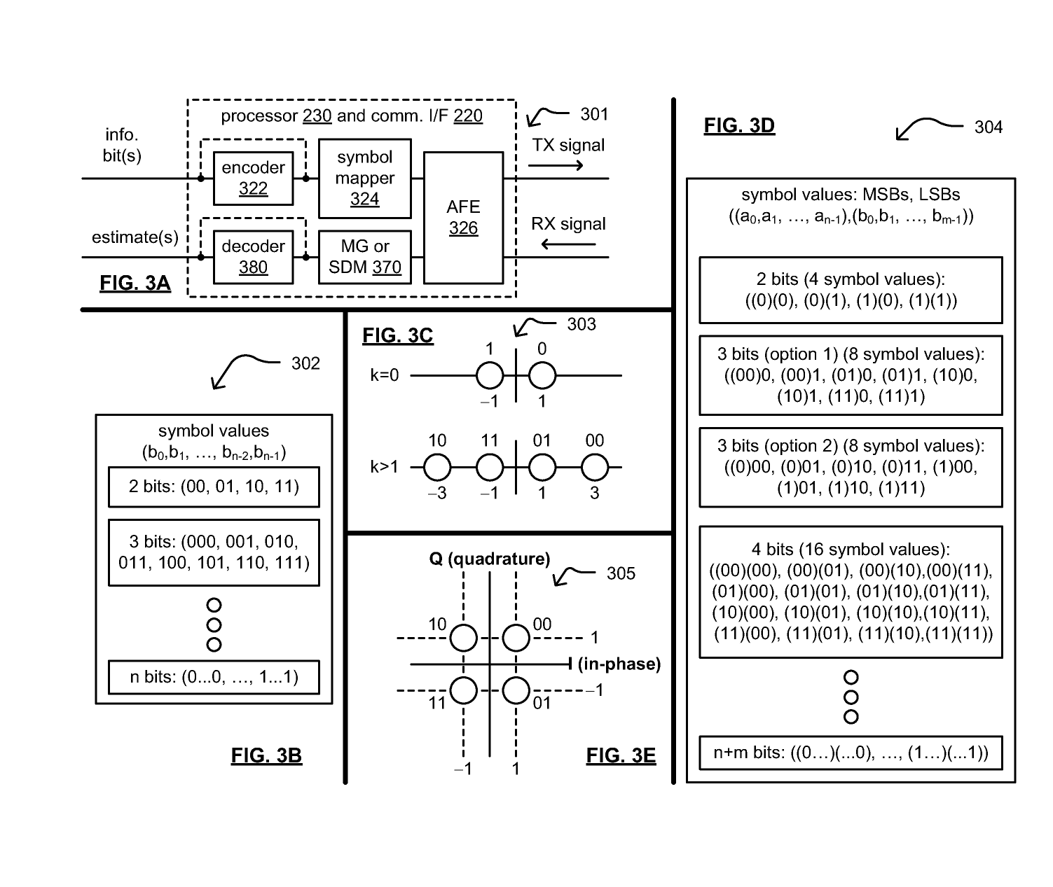

FIG. 3A is a diagram illustrating an example 301 of encoding and symbol mapping and symbol de-mapping and decoding. This diagram may be viewed as including processor 230 and communication interface 220 such as may be implemented in a communication device 110 (or 112) that includes functionality and capability to perform encoding, symbol mapping, analog front end (AFE), symbol de-mapping, metric generation, decoding, etc. related functions. In particular, the processor 230 and communication interface 220 includes encoder 322 that encodes information bits using one or more forward error correction (FEC) codes and/or error correction codes (ECCs) to generate coded bits that are arranged into data symbols. A symbol mapper 324 maps the data symbols to a constellation whose constellation maps are mapped according to a mapping (e.g., such as described herein) to generate modulation symbols. An analog front end (AFE) 326 processes the modulation symbols to generate a transmission signal (TX signal) (e.g., a continuous-time transmit signal). The AFE 326 can perform any of a variety of functions including scaling, digital to analog converter (DAC) conversion, analog to digital converter (ADC) conversion, frequency shifting, scaling, filtering, etc. to generate a transmission signal suitable to transmit to another communication device via communication link and/or receive a received signal (RX signal) from the another communication device via the communication link.

The AFE 326 also can process the RX signal to generate a digital and/or baseband signal. A metric generator or symbol de-mapper 370 processes the digital and/or baseband signal to generate estimates of data symbols within the digital and/or baseband signal (e.g., including symbol de-mapping). A decoder 380 processes the estimates of data symbols based on the one or more FEC codes and/or ECCs to generate estimates of information bits encoded therein. The functions of these elements are as previously described. In addition to the functionality as previously described, this embodiment provides a bypass of the encoder 322 and the decoder 380. As such, for certain applications, the information bits may be directly mapped to constellation points on the constellation map.

Also, it is noted that any such desired modulation (e.g., constellation points with associated mapping/labeling of the constellation points therein) may be implemented in any of a variety of ways (e.g., look up table (LUT) [such that a symbol of bit label is mapped to a respective constellation point based on the LUT] in some form of memory, via real-time calculation using one or more processors [such as a digital signal processor (DSP)], etc. and/or any such combination of means). For example, some embodiments will store the modulation in a LUT and/or memory for relatively smaller sized constellations (e.g., including constellation points below some desired or predetermined value), and use real-time calculation to generate the modulation for relatively larger sized constellations (e.g., including constellation points equal to or above some desired or predetermined value). For example, relatively large sized constellations can require a relatively significant amount of memory, and real-time calculation may be more efficient in some embodiments.

FIG. 3B is a diagram illustrating an example 302 of symbol values. Symbol values may include any number of bits. For example, symbol values may include as few as one bit per symbol, being 0 and 1. In other situations, symbol values may include two bits per symbol, three bits per symbol, or anywhere up to n bits per symbol (where n is a positive integer greater than or equal to 1). Generally, each of the constellation points and symbol locations within a constellation will have a same number of bits per symbol.

This disclosure presents an algebraic formula that is used to generate the symbol locations and associated constellation point labels for all possible types of quadrature amplitude modulation (QAM) constellations. The process operates by using a recursive procedure starting with binary phase shift keying (BPSK) modulation. This recursive procedure can be implied to generate any desired size of modulation having various numbers of constellation points and symbol locations based on symbol values having any desired number of bits per symbol. This recursive procedure provides Gray code mapping for even constellations having symbol locations and labels represented by an even number of bits per symbol such as quadrature phase shift keying (QPSK), 16 QAM, 46 QAM, 256 QAM, 1024 QAM, 4096 QAM, etc. and even higher ordered modulations including more symbol locations. This recursive procedure also provides a least Gray code penalty mapping for odd constellations having symbol locations and labels represented by an odd number of bits per symbol such as 8 QAM, 32 QAM, 128 QAM, 512 QAM, 248 QAM, etc. and even higher ordered modulations including more symbol locations and constellation points.

A device can implement operations to perform the recursive procedure in hardware, software, a lookup table, memory, etc. The mappings presented in this disclosure offer very good performance on a variety of different types of coded signals, including various low density parity check (LDPC) codes that may be used in applications that comply with various standards, communication protocols, and/or recommended practices such as prior versions of DOCSIS and/or DOCSIS 3.1 as well as EPoC (Ethernet Passive Optical Network Over Coaxial), EPON (Ethernet Passive Optical Networks), etc. and including various LDPC codes such as long size (16200, 14400) code for both downstream and upstream applications, medium size (5940, 5040) code for upstream applications, and short size (1120, 840) code for upstream applications.

FIG. 3C is a diagram illustrating an example 303 of Gray code mapping for integers (e.g., 2^{k} integers) in one-dimension. A Gray code for binary numbers is presented that lists all n-bit numbers so that successive numbers differ in exactly one bit position. When viewing a constellation, the symbol labels of constellation points that are nearest to a given constellation point will have symbol labels that differ in exactly one bit position. As an example, consider a 3 bit symbol label for constellation point having a value of 111, then a nearest other constellation point will have a symbol value differing in only one bit (e.g., such as 011, 101, or 110). Note that there may be many different Gray code mappings that satisfy this constraint that successive numbers differ by exactly one bit position. The example provided above using 3 bit symbol labels shows that an adjacent constellation point to one having a value of 111 may be any one of 011, 101, or 110.

This disclosure presents a proposed Gray code mapping for 2^{k} integers, 2i−(2^{k}−1) (k=0, 1, . . . , 2^{k}−1).

For k=1, G₁(0)=1, G₁(1)=−1.

For k>1,

Gₖ(b₀b₁ . . . bₖ₋₁)=(1−2b₀)(2^{k-1}+Gₖ₋₁(b₁ . . . bₖ₋₁)), bᵢ=0 or 1 for i=0, 1, . . . , k−1

For example, consider that k=2, then

$$\{ \begin{matrix}{G}_{2} ( 00 ) = ( 2 + {G}_{1} ( 0 ) ) = 3 \\ {G}_{2} ( 01 ) = ( 2 + {G}_{1} ( 1 ) ) = 1 \\ {G}_{2} ( 10 ) = - ( 2 + {G}_{1} ( 0 ) ) = - 3 \\ {G}_{2} ( 11 ) = - ( 2 + {G}_{1} ( 1 ) ) = - 1\end{matrix}$$

Note that the symbol locations of G₁(0) and G₁(1) are used to determine the symbol locations of G₂(00), G₂(01), G₂(10), and G₂(11). As may be understood with respect to the recursive nature of the one-dimensional breakout formula, a first one-dimensional Gray code symbol location for a first symbol value based on a second one-dimensional Gray code symbol location for a second symbol value having one fewer bits per symbol than the first symbol value.

For even higher ordered modulations (e.g., consider symbol values including 3 bits per symbol value), the symbol locations of G₂(00), G₂(01), G₂(10), and G₂(11) would be used to generate the 8 symbol locations of G₃(000), G₃(001), and so on up to G₃(111). Similarly, for symbol values including 4 bits per symbol value, the 8 symbol locations of G₃(000), G₃(001), and so on up to G₃(111) would be used to generate the 16 symbol locations of G₄(0000), G₄(0001), and so on up to G₄(1111). Note that the recursive one-dimensional Gray code formula as applied to this diagram is shown with respect to a singular dimension across the horizontal axis, or in-phase (I) axis. Alternatively, this recursive one-dimensional Gray code formula could alternatively be applied with respect to a singular dimension across the vertical axis, or quadrature (Q) axis. Generally, such a recursive one-dimensional Gray code formula could be applied along any axis in any direction within a constellation.

FIG. 3D is a diagram illustrating another example 304 of symbol values partitioned into most significant bits (MSBs) and least significant bits (LSBs). This diagram shows symbol values as being partitioned into a left hand side composed of one or more most significant bits (MSBs) and a right hand side composed of one or more least significant bits (LSBs).

For example, consider a symbol label or value, d, that includes n+m bits (where each of n and m are positive integers each greater than or equal to 1), then

d=a₀a₁ . . . aₙ₋₁b₀b₁ . . . bₘ₋₁

Then, the MSBs of d include a₀a₁ . . . aₙ₋₁.

The LSBs of d include b₀b₁ . . . bₘ₋₁.

The recursive one-dimensional Gray code formula described above can then be applied each of the MSBs and the LSBs in each of two different axes of a constellation. For example, the recursive one-dimensional Gray code formula can be applied to the MSBs in the horizontal or I axis and applied to the LSBs in the vertical or Q axis, or vice versa. When symbol labels are partitioned into a left hand side and a right hand side or MSBs and the LSBs, then the recursive one-dimensional Gray code formula can be applied to determine the symbol locations for a constellation.

Referring to FIG. 3D, note that there may be instances in which symbol labels include 2 bits per symbol such that there are 4 symbol values, and each symbol label includes 1 bit for the MSB and 1 bit for the LSB. In another example in which symbol labels include 3 bits per symbol such that there are 8 symbol values, there are at least two options in which the symbol values may be partitioned into MSBs and LSBs. In option 1, the MSBs are the 2 leftmost bits and the LSB is the rightmost bit. In option 2, the MSB is the 1 leftmost bit and the LSBs are the 2 rightmost bits. For symbol values including an odd number of bits per symbol, the bits may be partitioned into MSBs and LSBs in either way. For example, for symbol values including 5, 7, 9, or even higher numbers of odd bits per symbol, or generally considering a number of x bits per symbol, where x is a positive odd number greater than or equal to 3, then the MSBs may be the leftmost ((x−1)/2)+1 bits and the LSBs may be the rightmost ((x−1)/2) bits. Alternatively, the MSBs may be the leftmost ((x−1)/2) bits and the LSBs may be the rightmost ((x−1)/2)+1 bits.

Generally, for symbol values including an even number of bits per symbol, the bits may be partitioned into MSBs and LSBs as follows for a label or value, d:

d=a₀a₁ . . . aₙ₋₁b₀b₁ . . . bₘ₋₁

Then, the MSBs of d include a₀a₁ . . . aₙ₋₁.

The LSBs of d include b₀b₁ . . . bₘ₋₁.

FIG. 3E is a diagram illustrating an example 305 of Gray code mapping for integers (e.g., 2^{k} integers) in two-dimensions. Considering 2^{n+m} Rectangular constellation points as follows:

{(2i−(2ⁿ−1), 2j−(2^{m}−1))|i=0, 1, . . . , 2ⁿ−1, j=0, 1, . . . , 2^{m}−1}, then the mapping 2-D symbols with (n+m) binary bits using 1-D Gray code mapping is applied as follows:

Let d=a₀a₁ . . . aₙ₋₁b₀b₁ . . . bₘ₋₁

(I_{rct}(d),Q_{rct}(d))=(Gₙ(a₀a₁ . . . aₙ₋₁),Gₘ(b₀b₁ . . . , bₘ₋₁))

The recursive one-dimensional Gray code formula is applied to each of the MSBs of d that include a₀a₁ . . . aₙ₋₁ and to the LSBs of d that include b₀b₁ . . . bₘ₋₁. This determines the two-dimensional symbol locations for the constellation by applying the recursive one-dimensional Gray code formula along each of the I and Q axes. Note that I and Q are mapped independently (or in orthogonal).

Considering an example in which n=m=1 for a quadrature phase shift keying (QPSK) modulation, then:

(I_{rct}(00),Q_{rct}(00))=(G₁(0),G₁(0))=(1,1),(I_{rct}(01),Q_{rct}(01))=(G₁(0),G₁(1))=(1,−1)

(I_{rct}(10),Q_{rct}(10))=(G₁(1),G₁(0))=(−1,1),(I_{rct}(11),Q_{rct}(11))=(G₁(1),G₁(1))=(−1,−1)

Note that the recursive one-dimensional Gray code formula along each of the I and Q axes for each of the 1 MSB bit and 1 LSB bit of each of the 4 symbol values ((0)(0), (0)(1), (1)(0), and (1)(1)).

Depending on the number of bits per symbol value, the resulting constellation may have a square shape or a rectangular shape. Note that there is a special case with respect to a square constellation (e.g., for 2²ⁿ-QAM points, where {(2i−(2ⁿ−1), 2j−(2ⁿ−1))|i=0, 1, . . . , 2ⁿ−1, j=0, 1, . . . , 2ⁿ−1}).

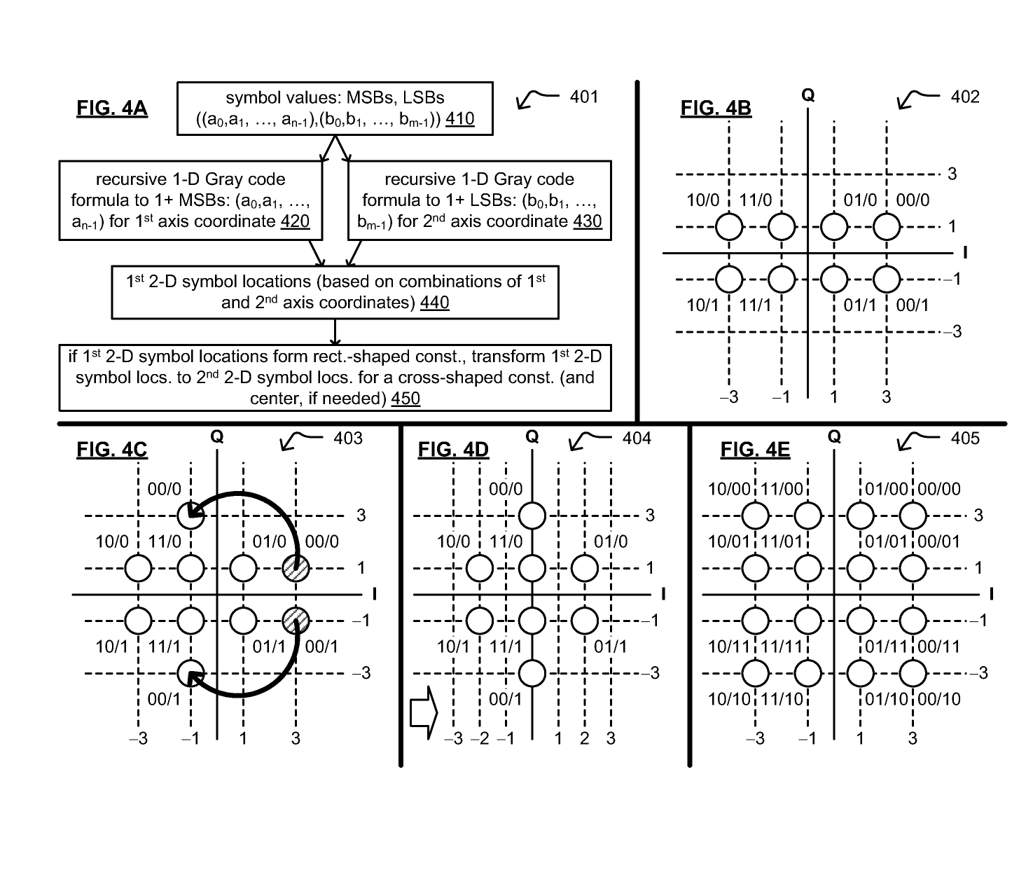

FIG. 4A is a diagram illustrating another example 401 of generation of a constellation mapping for data symbols based on MSBs and LSBs. Consider symbol values as being partitioned into MSBs and LSBs (block 410). The left hand side of the symbol values are the MSBs and the right hand side of the symbol values are the LSBs as follows:

d=a₀a₁ . . . aₙ₋₁b₀b₁ . . . bₘ₋₁

Then, the MSBs of d include a₀a₁ . . . aₙ₋₁.

The LSBs of d include b₀b₁ . . . bₘ₋₁.

The recursive one-dimensional Gray code formula is applied to the MSBs, a₀a₁ . . . aₙ₋₁ to generate a first axis coordinate for each respective symbol value (block 420). Then recursive one-dimensional Gray code formula is applied to the LSBs, b₀b₁ . . . bₘ₋₁ to generate a second axis coordinate for each respective symbol value (block 430). For example, these first and second axis coordinates may correspond to the I,Q values that determine the symbol locations for each of the constellation points within the constellation in generating a first set of two-dimensional symbol locations that are based on combinations of the first and second axis coordinates (block 440).

If the first set of two-dimensional symbol locations that are based on combinations of the first and second axis coordinates form a rectangular-shaped constellation, then the constellation points of the first set of two-dimensional symbol locations are transformed to a second set of two-dimensional symbol locations that is a cross-shaped constellation (block 450). Also, in the instance in which the resulting cross-shaped constellation is not centered around the origin of the constellation, then the resulting cross-shaped constellation may be translated along the appropriate access to center the constellation points around the origin of the constellation. The transformation from a rectangular-shaped constellation to a cross-shaped constellation reduces the required power of symbol locations or constellation points that are relatively farthest from the origin of the constellation.

FIG. 4B is a diagram illustrating an example 402 of Gray code mapping for integers in two-dimensions that results in a rectangle-shaped constellation. As mentioned above, depending on the number of bits per symbol value, the resulting constellation may have a square shape or a rectangular shape. This example is 8 QAM that includes 3 bits per symbol such that the MSBs are the 2 leftmost bits of each symbol value and the LSB is the 1 rightmost bit of each symbol value. The recursive one-dimensional Gray code formula is applied to the LSB for the vertical or quadrature (Q) directional axis, and the recursive one-dimensional Gray code formula is applied to the MSBs in the horizontal or in-phase (I) directional axis. As can be seen, the resulting set of two-dimensional symbol locations form a rectangular-shaped constellation.

FIG. 4C is a diagram illustrating an example 403 of transformation of a rectangle-shaped constellation to a cross-shaped constellation (based on FIG. 4B). Because the resulting set of two-dimensional symbol locations form a rectangular-shaped constellation as described above is a rectangular-shaped constellation, constellation points from the right hand side wing of the rectangular-shaped constellation are re-assigned to be above and below the constellation. In this example, one symbol location from the right hand side wing is re-assigned to be above the constellation, and another symbol location from the right hand side wing is re-assigned to be below the constellation.

For example, starting with a rectangular constellation mapping (e.g., from FIG. 4B)

d=a₀a₁b₀

(I_{rct}(d),Q_{rct}(d))=(G₂(a₀a₁),G₁(b₀))

Then, because the resulting constellation is rectangular-shaped, certain symbol locations within the rectangular-shaped constellation are transformed to generate a cross-shaped constellation. However, it can be seen that the symbol locations within the resulting cross-shaped constellation are not centered around the origin of the constellation.

FIG. 4D is a diagram illustrating an example 404 of shifting of a cross-shaped constellation to center the cross-shaped constellation around an origin (based on FIG. 4C). This diagram shows the shifting of the cross-shaped constellation of FIG. 4C to the right along the I axis so that the symbol locations of the cross-shaped constellation are in fact centered around the origin.

The transformation of the right hand side wing of the rectangular-shaped constellation to generate the cross-shaped constellation and the shift operation applied to the cross-shaped constellation that is not centered around the origin of the constellation may be described mathematically as follows:

$$\{ \begin{matrix}\{ \begin{matrix}{I}_{cr} ( d ) = {I}_{rct} ( d ) + 1 \\ {Q}_{cr} ( d ) = {Q}_{rct} ( d )\end{matrix} & {I}_{rct} ( d ) < 3 \\ \{ \begin{matrix}{I}_{cr} ( d ) = - sign ( {I}_{rct} ( d ) ( 4 - \vert {I}_{rct} ( d ) \vert ) + 1 \\ {Q}_{cr} ( d ) = sign ( {Q}_{rct} ( d ) ) ( \vert {Q}_{rct} ( d ) \vert + 2 )\end{matrix} & otherwise\end{matrix} \\ \{ \begin{matrix}{I}_{cr} ( 000 ) = - ( 4 - 3 ) + 1 = 0 \\ {Q}_{cr} ( 000 ) = ( 1 + 2 ) = 3\end{matrix} \\ \{ \begin{matrix}{I}_{cr} ( 001 ) = - ( 4 - 3 ) + 1 = 0 \\ {Q}_{cr} ( 001 ) = - ( 1 + 2 ) = - 3\end{matrix}$$

With minimal Gray code penalty, Gₚ, as follows:

$${G}_{P} = \frac{1}{8} ( 2 + 1 + \frac{5}{4} + 1 + 1 + \frac{5}{4} + 1 + 2 ) = \frac{21}{16} = 1.3125$$

Note that the variables of I and Q correspond to the I and Q axes of the constellation, the subscripts “cr” correspond to the cross-shaped constellation, and the subscripts “rct” correspond to the rectangular-shaped constellation. This convention is also used in other examples provided herein.

Note that the transformation from a square-shaped constellation to cross-shaped constellation may incur a Gray code penalty. Such a great code penalty has been defined by Joel G. Smith in the following reference, “Odd-bit quadrature amplitude shift keying,” IEEE Trans. Commun., vol. COMM-23, no. 3, pp. 385-389, March 1975.

In that reference, it is described that all one-dimensional Gray codes and two-dimensional Gray codes of orthogonal components are pure. All other Gray codes are “impure,” and suffer a “Gray code penalty”.

Mathematically, this may be described as follows:

2ⁿ−QAM, there are 2ⁿ symbols, Sᵢ, i=0, 1, . . . , 2ⁿ−1

N(Sᵢ)={Sⱼ|Sⱼ is the nearest (in Euclidean distance) neighbors of Sᵢ}

l(S): binary labeling given by the mapping

wt(l(Sᵢ), l(Sⱼ)): hamming distance between l(Sᵢ) and l(Sⱼ)

Gray Code Penalty:

$${G}_{P} ( l ) = \frac{1}{{2}^{n}} {\sum }_{i = 0}^{{2}^{n} - 1} \frac{{\sum }_{{S}_{j} ∈ N ( {S}_{i} )} wt ( l ( {S}_{j} ) , l ( {S}_{i} ) )}{\vert N ( {S}_{i} ) \vert}$$

Note that if/provides a Gray code mapping then G_{P}(1)=1, there is no penalty. The proposed mapping on rectangular-shaped constellation as described in this disclosure has G_{P}=1.

FIG. 4E is a diagram illustrating an example 405 of Gray code mapping for integers in two-dimensions that results in a square-shaped constellation. As mentioned above, depending on the number of bits per symbol value, the resulting constellation may have a square shape or a rectangular shape. Note that there is a special case with respect to a square constellation (e.g., for 2²ⁿ-QAM points, where {(2i−(2ⁿ−1), 2j−(2ⁿ−1))|i=0, 1, . . . , 2ⁿ−1, j=0, 1, . . . , 2ⁿ−1}). The specific example of 16 QAM that includes 4 bits per symbol such that the MSBs are the 2 leftmost bits of each symbol value and the LSBs are the 2 rightmost bits of each symbol value.

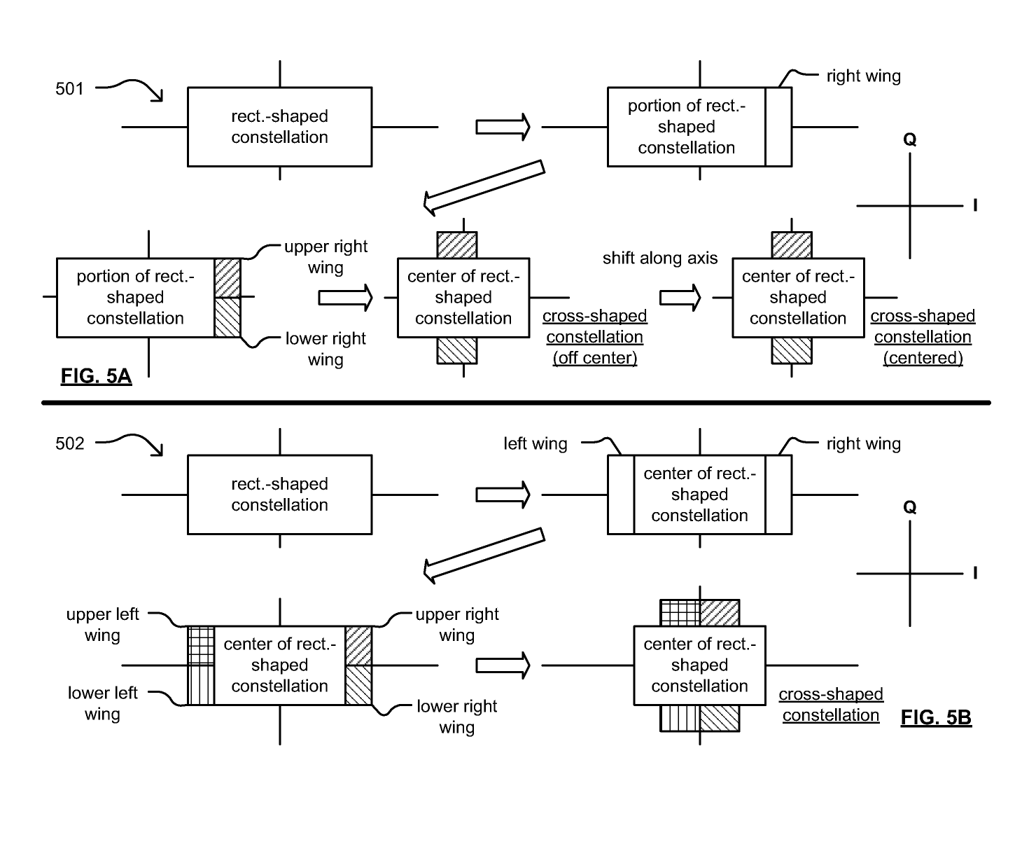

FIG. 5A is a diagram illustrating an example 501 of Gray code mapping for integers in two-dimensions for cross-shaped constellations (e.g., 2²ⁿ⁺¹ QAM, where n>1). Referring to the mapping on the cross-shaped constellation that results when using symbol values having an odd number of bits per symbol, the operations may be described by starting with an n×(n+1) rectangular-shaped constellation (where n is a positive integer). Because the constellation is rectangular-shaped, it is transformed by re-assigning symbol locations within the one of vertical wings (e.g., on the right hand side to above and below the constellation. A pseudo-Gray code mapping is applied on the re-assigning symbol locations (with the least Gray Code Penalty).

In this example 502, the resulting cross-shaped constellation is off-center with respect to the origin of the constellation. As such, the resulting cross-shaped constellation is shifted along the horizontal axis so that the final cross-shaped constellation is centered around the origin of the constellation.

FIG. 5B is a diagram illustrating another example 502 of Gray code mapping for integers in two-dimensions for cross-shaped constellations (e.g., 2²ⁿ⁺¹ QAM, where n>1). Referring to the mapping on the cross-shaped constellation that results when using symbol values having an odd number of bits per symbol, the operations may be described by starting with a n×(n+1) rectangular-shaped constellation. Because the constellation is rectangular-shaped, it is transformed by re-assigning symbol locations within the two vertical wings on the left and right hand side to two horizontal wings above and below. A pseudo-Gray code mapping is applied on the two horizontal wings (with the least Gray Code Penalty) using the following algebraic formula.

$$d = {a}_{0} {a}_{1} … {a}_{n} {b}_{0} {b}_{1} … {d}_{n - 1}$$

$$( {I}_{rct} ( d ) , {Q}_{rct} ( d ) ) = ( {G}_{n + 1} ( {a}_{0} {a}_{1} … {a}_{n - 1} ) , {G}_{n} ( {b}_{0} {b}_{1} … , {b}_{n - 1} ) )$$

$$Let s = {2}^{n - 1}$$

$$\{ \begin{matrix}\{ \begin{matrix}{I}_{cr} ( d ) = {I}_{rct} ( d ) \\ {Q}_{cr} ( d ) = {Q}_{rct} ( d )\end{matrix} & if \vert {I}_{rct} ( d ) \vert < 3 s \\ \{ \begin{matrix}\{ \begin{matrix}{I}_{cr} ( d ) = sign ( {I}_{rct} ( d ) ) ( \vert {I}_{rct} ( d ) \vert - 2 s ) \\ {Q}_{cr} ( d ) = sign ( {Q}_{rct} ( d ) ) ( 4 s - \vert {Q}_{rct} ( d ) \vert )\end{matrix} & \vert {Q}_{rct} ( d ) \vert > s \\ \{ \begin{matrix}{I}_{cr} ( d ) = sign ( {I}_{rct} ( d ) ) ( 4 s - \vert {I}_{rct} ( d ) \vert ) \\ {Q}_{cr} ( d ) = sign ( {Q}_{rct} ( d ) ) ( \vert {Q}_{rct} ( d ) \vert + 2 s )\end{matrix} & \vert {Q}_{rct} ( d ) \vert \leq s\end{matrix} & otherwise\end{matrix}$$

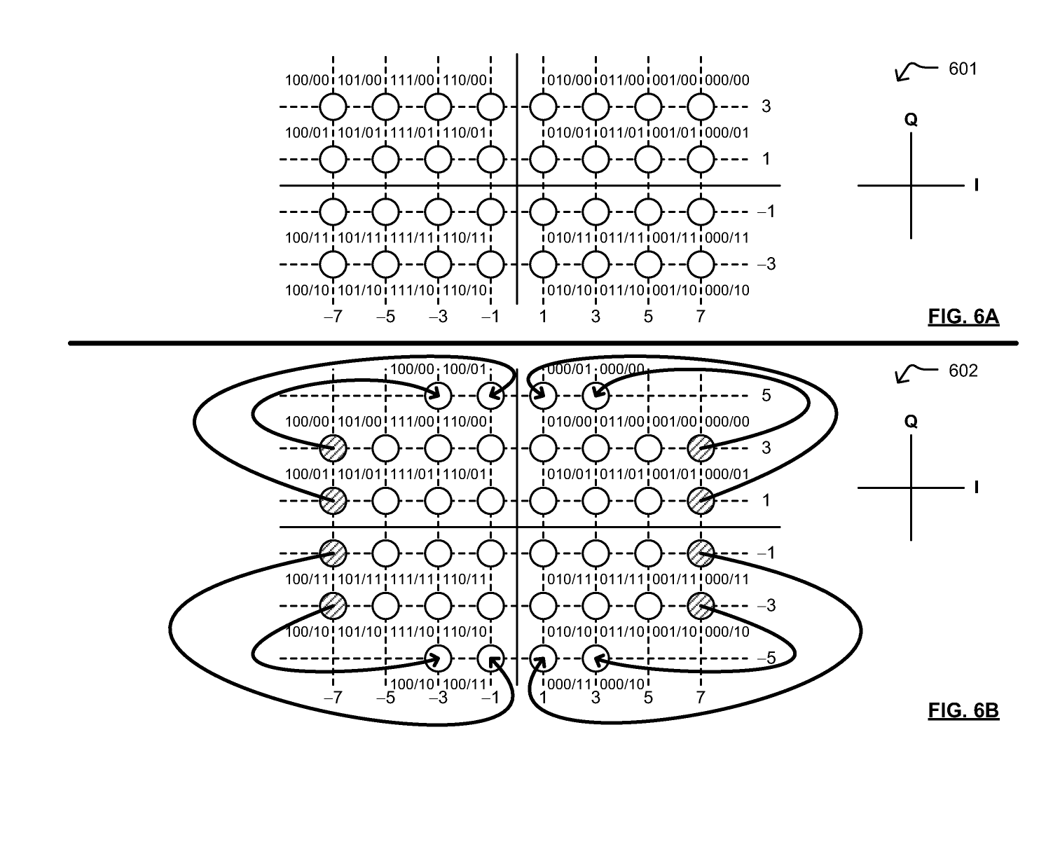

The following FIG. 6A and FIG. 6B show a specific example of using symbol values of 5 bits per symbol such that the MSBs are the 3 leftmost bits of each symbol value and the LSBs are the 2 right most bits of each symbol value.

FIG. 6A is a diagram illustrating another example 601 of transformation of a rectangle-shaped constellation to a cross-shaped constellation. The first set of two-dimensional symbol locations includes 32 constellation points in a rectangular-shaped constellation.

FIG. 6B is a diagram illustrating another example 602 of transformation of a rectangle-shaped constellation to a cross-shaped constellation (based on FIG. 6A). Because the constellation is rectangular-shaped, it is transformed by re-assigning symbol locations within the two vertical wings on the left and right hand side to two horizontal wings above and below. A pseudo-Gray code mapping is applied on the two horizontal wings (with the least Gray Code Penalty) using the following algebraic formula.

$$d = {a}_{0} {a}_{1} {a}_{2} {b}_{0} {b}_{1}$$

$$( {I}_{rct} ( d ) , {Q}_{rct} ( d ) ) = ( {G}_{3} ( {a}_{0} {a}_{1} {a}_{2} ) , {G}_{2} ( {b}_{0} {b}_{1} ) )$$

$$Let s = 2$$

$$\{ \begin{matrix}\{ \begin{matrix}{I}_{cr} ( d ) = {I}_{rct} ( d ) \\ {Q}_{cr} ( d ) = {Q}_{rct} ( d )\end{matrix} & if \vert {I}_{rct} ( d ) \vert < 6 \\ \{ \begin{matrix}\{ \begin{matrix}{I}_{cr} ( d ) = sign ( {I}_{rct} ( d ) ) ( \vert {I}_{rct} ( d ) \vert - 4 ) \\ {Q}_{cr} ( d ) = sign ( {Q}_{rct} ( d ) ) ( 8 - \vert {Q}_{rct} ( d ) \vert )\end{matrix} & \vert {Q}_{rct} ( d ) \vert > 2 \\ \{ \begin{matrix}{I}_{cr} ( d ) = sign ( {I}_{rct} ( d ) ) ( 8 - \vert {I}_{rct} ( d ) \vert ) \\ {Q}_{cr} ( d ) = sign ( {Q}_{rct} ( d ) ) ( \vert {Q}_{rct} ( d ) \vert + 4 )\end{matrix} & \vert {Q}_{rct} ( d ) \vert \leq 2\end{matrix} & otherwise\end{matrix}$$

and specifically with respect to this particular diagram, the values are calculated as follows:

$$\{ \begin{matrix}{I}_{cr} ( 00000 ) = ( 7 - 4 ) = 3 \\ {Q}_{cr} ( 0000 ) = ( 8 - 3 ) = 5\end{matrix} \\ \{ \begin{matrix}{I}_{cr} ( 00001 ) = ( 8 - 7 ) = 1 \\ {Q}_{cr} ( 00001 ) = ( 1 + 4 ) = 5\end{matrix} \\ \{ \begin{matrix}{I}_{cr} ( 00011 ) = ( 8 - 7 ) = 1 \\ {Q}_{cr} ( 00011 ) = - ( 1 + 4 ) = - 5\end{matrix} \\ \{ \begin{matrix}{I}_{cr} ( 00010 ) = ( 7 - 4 ) = 3 \\ {Q}_{cr} ( 00010 ) = - ( 8 - 3 ) = - 5\end{matrix} \\ \{ \begin{matrix}{I}_{cr} ( 10000 ) = - ( 7 - 4 ) = - 3 \\ {Q}_{cr} ( 10000 ) = ( 8 - 3 ) = 5\end{matrix} \\ \{ \begin{matrix}{I}_{cr} ( 10001 ) = - ( 8 - 7 ) = - 1 \\ {Q}_{cr} ( 10001 ) = ( 1 + 4 ) = 5\end{matrix} \\ \{ \begin{matrix}{I}_{cr} ( 10011 ) = - ( 8 - 7 ) = - 1 \\ {Q}_{cr} ( 10011 ) = - ( 1 + 4 ) = - 5\end{matrix} \\ \{ \begin{matrix}{I}_{cr} ( 10010 ) = - ( 7 - 4 ) = - 3 \\ {Q}_{cr} ( 10010 ) = - ( 8 - 3 ) = - 5\end{matrix}$$

With minimal Gray code penalty, Gₚ, as follows:

$$\begin{matrix}{G}_{P} = \frac{2}{32} ( 3 / 2 + 4 / 3 + 4 / 3 + 3 / 2 + 1 + 5 / 4 + 5 / 4 + 5 / 4 + 5 / 4 + 1 + 6 ) \\ = 7 / 6 \\ = 1.1667\end{matrix}$$

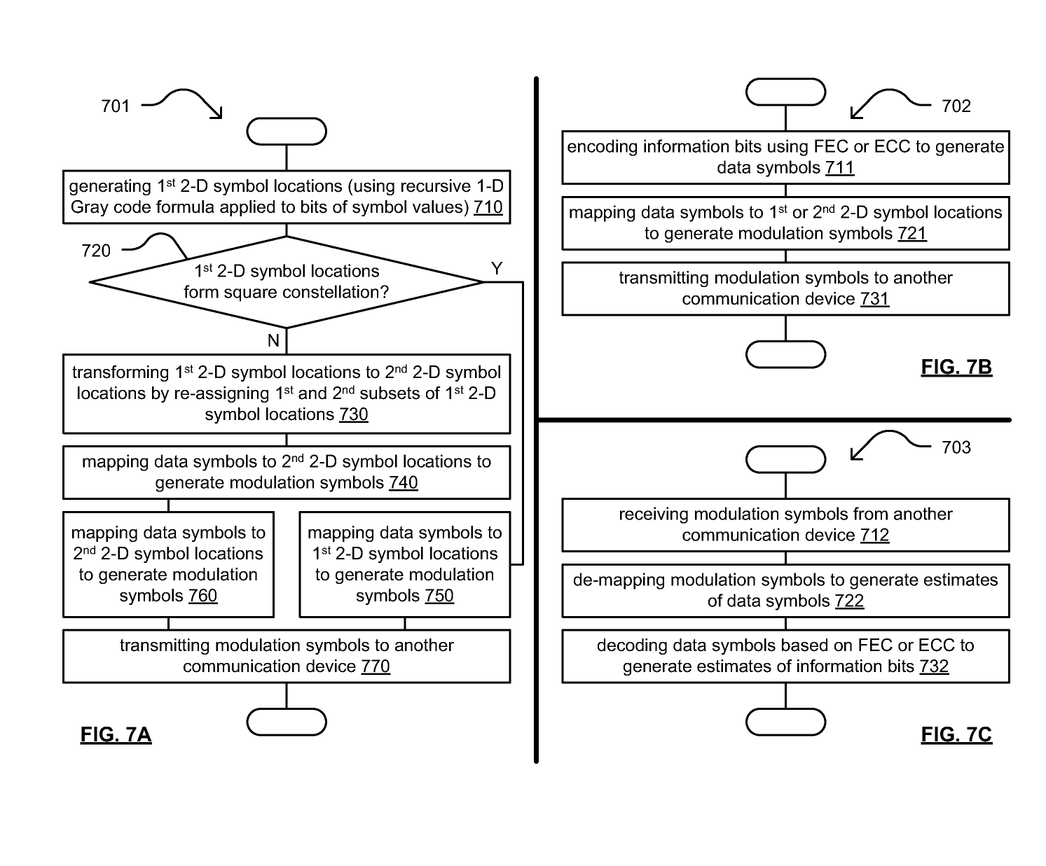

FIG. 7A is a diagram illustrating an embodiment of a method 701 for execution by one or more communication devices. The method 701 begins by generating a first plurality of two-dimensional symbol locations for a constellation based on a recursive one-dimensional Gray code formula applied to a first at least one bit and a second at least one bit of each symbol value of a plurality of symbol values (block 710). The recursive one-dimensional Gray code formula specifies a first one-dimensional Gray code symbol location for a first symbol value based on a second one-dimensional Gray code symbol location for a second symbol value having one fewer bits per symbol than the first symbol value.

The method 701 continues by determining whether the first plurality of two-dimensional symbol locations form a square-shaped constellation (block 720) (e.g., if the two-dimensional symbol locations compare favorably to form a square-shaped constellation).

When the first plurality of two-dimensional symbol locations form the square-shaped constellation, the method 701 then operates by mapping a plurality of data symbols to the first plurality of two-dimensional symbol locations to generate a plurality of modulation symbols when the first plurality of two-dimensional symbol locations form the square-shaped constellation (block 750).

Alternatively, when the first plurality of two-dimensional symbol locations do not form a square-shaped constellation, the method 701 continues by transforming the first plurality of two-dimensional symbol locations to a second plurality of two-dimensional symbol locations by re-assigning a first subset and a second subset of the first plurality of two-dimensional symbol locations (block 730). The second plurality of two-dimensional symbol locations form a cross-shaped constellation.

The method 701 continues by mapping the plurality of data symbols to the second plurality of two-dimensional symbol locations to generate the plurality of modulation symbols (block 760).

The method 701 then operates by transmitting, via a communication interface of the communication device, the plurality of modulation symbols to another communication device (block 770). This plurality of modulation symbols that get transmitted are generated based on either the first or second plurality of two-dimensional symbol locations.

FIG. 7B is a diagram illustrating another embodiment of a method 702 for execution by one or more communication devices. The method 702 begins by encoding information bits using FEC or ECC to generate data symbols (block 711). The method 702 continues by mapping data symbols to 1^{st} or 2^{nd} 2-D symbol locations to generate modulation symbols (block 721). The method 702 then operates by transmitting modulation symbols to another communication device (block 731).

FIG. 7C is a diagram illustrating another embodiment of a method 703 for execution by one or more communication devices. The method 703 begins by receiving modulation symbols from another communication device (block 712). The method 703 continues by de-mapping modulation symbols to generate estimates of data symbols (block 722). The method 703 then operates by decoding data symbols based on FEC or ECC to generate estimates of information bits (block 732).

This disclosure has presented a recursive constellation mapping procedure that may be applied to any desired application including those standards, communication protocols, and/or recommended practices described herein such as DOCSIS and/or DOCSIS 3.1 as well as EPoC (Ethernet Passive Optical Network Over Coaxial), EPON (Ethernet Passive Optical Networks), etc. and including various LDPC codes such as long size (16200, 14400) code for both downstream and upstream applications, medium size (5940, 5040) code for upstream applications, and short size (1120, 840) code for upstream applications. This recursive procedure can be implemented in any one or more of a variety of ways including hardware logic, look up table, executable operations by a processor based on information and/or operational instructions stored in memory, etc. This recursive procedure may be applied on even-bit QAM constellations (e.g., 2²ⁿ QAM) and will result in a Gray code mapping. This recursive procedure may also be applied on odd-bits QAM constellation (e.g., 2²ⁿ⁺¹ QAM) and will result in a cross-shaped constellation. The cross-shaped constellation is been transformed from the Gray code mapping of rectangular constellation to a mapping with the least Gray code penalty (pseudo-Gray code). In certain performances and simulations, successive or consecutive constellations were shown to be approximately 3 dB apart in performance.

As may be used herein, the terms “substantially” and “approximately” provides an industry-accepted tolerance for its corresponding term and/or relativity between items. Such an industry-accepted tolerance ranges from less than one percent to fifty percent and corresponds to, but is not limited to, component values, integrated circuit process variations, temperature variations, rise and fall times, and/or thermal noise. Such relativity between items ranges from a difference of a few percent to magnitude differences. As may also be used herein, the term(s) “configured to,” “operably coupled to,” “coupled to,” and/or “coupling” includes direct coupling between items and/or indirect coupling between items via an intervening item (e.g., an item includes, but is not limited to, a component, an element, a circuit, and/or a module) where, for an example of indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”. As may even further be used herein, the term “configured to,” “operable to,” “coupled to,” or “operably coupled to” indicates that an item includes one or more of power connections, input(s), output(s), etc., to perform, when activated, one or more its corresponding functions and may further include inferred coupling to one or more other items. As may still further be used herein, the term “associated with,” includes direct and/or indirect coupling of separate items and/or one item being embedded within another item.

As may be used herein, the term “compares favorably” or equivalent, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1.

As may also be used herein, the terms “processing module,” “processing circuit,” “processor,” and/or “processing unit” may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module, module, processing circuit, and/or processing unit may be, or further include, memory and/or an integrated memory element, which may be a single memory device, a plurality of memory devices, and/or embedded circuitry of another processing module, module, processing circuit, and/or processing unit. Such a memory device may be a read-only memory, random access memory, volatile memory, non-volatile memory, static memory, dynamic memory, flash memory, cache memory, and/or any device that stores digital information. Note that if the processing module, module, processing circuit, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processing module, module, processing circuit, and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processing module, module, processing circuit, and/or processing unit executes, hard coded and/or operational instructions corresponding to at least some of the steps and/or functions illustrated in one or more of the Figures. Such a memory device or memory element can be included in an article of manufacture.

One or more embodiments of an invention have been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality. To the extent used, the flow diagram block boundaries and sequence could have been defined otherwise and still perform the certain significant functionality. Such alternate definitions of both functional building blocks and flow diagram blocks and sequences are thus within the scope and spirit of the claimed invention. One of average skill in the art will also recognize that the functional building blocks, and other illustrative blocks, modules and components herein, can be implemented as illustrated or by discrete components, application specific integrated circuits, processors executing appropriate software and the like or any combination thereof.

The one or more embodiments are used herein to illustrate one or more aspects, one or more features, one or more concepts, and/or one or more examples of the invention. A physical embodiment of an apparatus, an article of manufacture, a machine, and/or of a process may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

Unless specifically stated to the contra, signals to, from, and/or between elements in a figure of any of the figures presented herein may be analog or digital, continuous time or discrete time, and single-ended or differential. For instance, if a signal path is shown as a single-ended path, it also represents a differential signal path. Similarly, if a signal path is shown as a differential path, it also represents a single-ended signal path. While one or more particular architectures are described herein, other architectures can likewise be implemented that use one or more data buses not expressly shown, direct connectivity between elements, and/or indirect coupling between other elements as recognized by one of average skill in the art.

The term “module” is used in the description of one or more of the embodiments. A module includes a processing module, a processor, a functional block, hardware, and/or memory that stores operational instructions for performing one or more functions as may be described herein. Note that, if the module is implemented via hardware, the hardware may operate independently and/or in conjunction with software and/or firmware. As also used herein, a module may contain one or more sub-modules, each of which may be one or more modules.

While particular combinations of various functions and features of the one or more embodiments have been expressly described herein, other combinations of these features and functions are likewise possible. The present disclosure of an invention is not limited by the particular examples disclosed herein and expressly incorporates these other combinations.

What is claimed is:

1. A communication device comprising:
a communication interface; and
a processor, the processor and the communication interface configured to:
generate a first plurality of two-dimensional symbol locations for a constellation based on a recursive one-dimensional Gray code formula applied to a first at least one bit and a second at least one bit of each symbol value of a plurality of symbol values, wherein the recursive one-dimensional Gray code formula specifies a first one-dimensional Gray code symbol location for a first symbol value based on a second one-dimensional Gray code symbol location for a second symbol value having one fewer bits per symbol than the first symbol value;
determine whether the first plurality of two-dimensional symbol locations form a square-shaped constellation;
map a plurality of data symbols to the first plurality of two-dimensional symbol locations to generate a plurality of modulation symbols when the first plurality of two-dimensional symbol locations form the square-shaped constellation;
transform the first plurality of two-dimensional symbol locations to a second plurality of two-dimensional symbol locations by re-assigning a first subset and a second subset of the first plurality of two-dimensional symbol locations when the first plurality of two-dimensional symbol locations do not form the square-shaped constellation, wherein the second plurality of two-dimensional symbol locations form a cross-shaped constellation;
map the plurality of data symbols to the second plurality of two-dimensional symbol locations to generate the plurality of modulation symbols when the first plurality of two-dimensional symbol locations do not form the square-shaped constellation; and
transmit the plurality of modulation symbols to another communication device.

2. The communication device of claim 1, wherein the processor and the communication interface are further configured to:
determine whether the second plurality of two-dimensional symbol locations are centered around an origin of the cross-shaped constellation; and
shift the second plurality of two-dimensional symbol locations along an axis of the cross-shaped constellation to center the second plurality of two-dimensional symbol locations around the origin of the cross-shaped constellation when the second plurality of two-dimensional symbol locations are not centered around the origin of the cross-shaped constellation.

3. The communication device of claim 1, wherein the processor and the communication interface are further configured to:
apply the recursive one-dimensional Gray code formula to a most significant at least one bit of one of the plurality of symbol values to generate a first axis coordinate value of one of the first plurality of two-dimensional symbol locations; and
apply the recursive one-dimensional Gray code formula to a least significant at least one bit of the one of the plurality of symbol values to generate a second axis coordinate value of the one of the first plurality of two-dimensional symbol locations.

4. The communication device of claim 3, wherein the one of the plurality of symbol values includes an odd number of bits, and the most significant at least one bit includes one bit more or one bit fewer than the least significant at least one bit.

5. The communication device of claim 3, wherein the one of the plurality of symbol values includes an even number of bits, and the most significant at least one bit includes a same number of bits as the least significant at least one bit.

6. The communication device of claim 1, wherein the processor and the communication interface are further configured to:
re-assign a first two-dimensional symbol location within the first subset of the first plurality of two-dimensional symbol locations from a wing of the first plurality of two-dimensional symbol locations to above the first plurality of two-dimensional symbol locations; and
re-assign a second two-dimensional symbol location within the first subset of the first plurality of two-dimensional symbol locations from the wing of the first plurality of two-dimensional symbol locations to below the first plurality of two-dimensional symbol locations to generate the second plurality of two-dimensional symbol locations.

7. The communication device of claim 1, wherein the processor and the communication interface are further configured to:
encode a plurality of information bits using a low density parity check (LDPC) code to generate the plurality of data symbols.

8. The communication device of claim 1 further comprising:
a cable modem, wherein the another communication device is a cable headend transmitter or a cable modem termination system (CMTS).

9. The communication device of claim 1 further comprising:
the processor and the communication interface configured to support communications within at least one of a satellite communication system, a wireless communication system, a wired communication system, a fiber-optic communication system, or a mobile communication system.

10. A communication device comprising:
a communication interface; and
a processor configured to:
apply a recursive one-dimensional Gray code formula to most significant bits of a plurality of symbol values to generate first axis coordinate values of a first plurality of two-dimensional symbol locations for a constellation, wherein the recursive one-dimensional Gray code formula specifies a first one-dimensional Gray code symbol location for a first symbol value based on a second one-dimensional Gray code symbol location for a second symbol value having one fewer bits per symbol than the first symbol value; and
apply the recursive one-dimensional Gray code formula to least significant bits of the plurality of symbol values to generate second axis coordinate values of the first plurality of two-dimensional symbol locations for the constellation;
determine whether the first plurality of two-dimensional symbol locations form a square-shaped constellation;
encode a plurality of information bits using a forward error correction (FEC) code or an error correction code (ECC) to generate a plurality of data symbols;
map the plurality of data symbols to the first plurality of two-dimensional symbol locations to generate a plurality of modulation symbols when the first plurality of two-dimensional symbol locations form the square-shaped constellation;
transform the first plurality of two-dimensional symbol locations to a second plurality of two-dimensional symbol locations by re-assigning a first subset and a second subset of the first plurality of two-dimensional symbol locations when the first plurality of two-dimensional symbol locations do not form the square-shaped constellation, wherein the second plurality of two-dimensional symbol locations form a cross-shaped constellation;
map the plurality of data symbols to the second plurality of two-dimensional symbol locations to generate the plurality of modulation symbols when the first plurality of two-dimensional symbol locations do not form the square-shaped constellation; and
transmit the plurality of modulation symbols to another communication device.

11. The communication device of claim 10, wherein the processor and the communication interface are further configured to:
determine whether the second plurality of two-dimensional symbol locations are centered around an origin of the cross-shaped constellation; and
shift the second plurality of two-dimensional symbol locations along an axis of the cross-shaped constellation to center the second plurality of two-dimensional symbol locations around the origin of the cross-shaped constellation when the second plurality of two-dimensional symbol locations are not centered around the origin of the cross-shaped constellation.

12. The communication device of claim 10, wherein the processor and the communication interface are further configured to:
re-assign a first two-dimensional symbol location within the first subset of the first plurality of two-dimensional symbol locations from a wing of the first plurality of two-dimensional symbol locations to above the first plurality of two-dimensional symbol locations; and
re-assign a second two-dimensional symbol location within the first subset of the first plurality of two-dimensional symbol locations from the wing of the first plurality of two-dimensional symbol locations to below the first plurality of two-dimensional symbol locations to generate the second plurality of two-dimensional symbol locations.

13. The communication device of claim 10 further comprising:
a cable modem, wherein the another communication device is a cable headend transmitter or a cable modem termination system (CMTS).

14. A method for execution by a communication device, the method comprising:
generating a first plurality of two-dimensional symbol locations for a constellation based on a recursive one-dimensional Gray code formula applied to a first at least one bit and a second at least one bit of each symbol value of a plurality of symbol values, wherein the recursive one-dimensional Gray code formula specifies a first one-dimensional Gray code symbol location for a first symbol value based on a second one-dimensional Gray code symbol location for a second symbol value having one fewer bits per symbol than the first symbol value;
determining whether the first plurality of two-dimensional symbol locations form a square-shaped constellation;
mapping a plurality of data symbols to the first plurality of two-dimensional symbol locations to generate a plurality of modulation symbols when the first plurality of two-dimensional symbol locations form the square-shaped constellation;
transforming the first plurality of two-dimensional symbol locations to a second plurality of two-dimensional symbol locations by re-assigning a first subset and a second subset of the first plurality of two-dimensional symbol locations when the first plurality of two-dimensional symbol locations do not form the square-shaped constellation, wherein the second plurality of two-dimensional symbol locations form a cross-shaped constellation;
mapping the plurality of data symbols to the second plurality of two-dimensional symbol locations to generate the plurality of modulation symbols when the first plurality of two-dimensional symbol locations do not form the square-shaped constellation; and
transmitting, via a communication interface of the communication device, the plurality of modulation symbols to another communication device.

15. The method of claim 14 further comprising:
determining whether the second plurality of two-dimensional symbol locations are centered around an origin of the cross-shaped constellation; and
shifting the second plurality of two-dimensional symbol locations along an axis of the cross-shaped constellation to center the second plurality of two-dimensional symbol locations around the origin of the cross-shaped constellation when the second plurality of two-dimensional symbol locations are not centered around the origin of the cross-shaped constellation.

16. The method of claim 14 further comprising:
applying the recursive one-dimensional Gray code formula to a most significant at least one bit of one of the plurality of symbol values to generate a first axis coordinate value of one of the first plurality of two-dimensional symbol locations; and
applying the recursive one-dimensional Gray code formula to a least significant at least one bit of the one of the plurality of symbol values to generate a second axis coordinate value of the one of the first plurality of two-dimensional symbol locations.

17. The method of claim 14 further comprising:
re-assigning a first two-dimensional symbol location within the first subset of the first plurality of two-dimensional symbol locations from a wing of the first plurality of two-dimensional symbol locations to above the first plurality of two-dimensional symbol locations; and
re-assigning a second two-dimensional symbol location within the first subset of the first plurality of two-dimensional symbol locations from the wing of the first plurality of two-dimensional symbol locations to below the first plurality of two-dimensional symbol locations to generate the second plurality of two-dimensional symbol locations.

18. The method of claim 14 further comprising:
encoding a plurality of information bits using a low density parity check (LDPC) code to generate the plurality of data symbols.

19. The method of claim 14, wherein the communication device is a cable modem, and the another communication device is a cable headend transmitter or a cable modem termination system (CMTS).

20. The method of claim 14 further comprising:
operating the communication interface of the communication device to support communications within at least one of a satellite communication system, a wireless communication system, a wired communication system, a fiber-optic communication system, or a mobile communication system.
